(19) United States
(12) Patent Application Publication
(10) Pub. No.: US 2026/0350381 A1
(43) Pub. Date: Nov. 5, 2026

(54) ANALOG CONTENT ADDRESSABLE MEMORY APPROXIMATING ACTIVATION FUNCTIONS

(71) Applicant: Hewlett Packard Enterprise Development LP, Spring, TX (US)

(72) Inventors: Giacomo Pedretti, Verbania (IT); Lei Zhao, Fort Collins, CO (US); Luca Buonanno, Fort Collins, CO (US)

(21) Appl. No.: 19/195,605

(22) Filed: Apr. 30, 2025

(51) Int. Cl. G06N 3/065; G06N 3/048; G06N 3/0495; G11C 15/04

(52) U.S. Cl. CPC G06N 3/065; G06N 3/048; G06N 3/0495; G11C 15/04

(57) ABSTRACT

Processing resources program one or more analog content-addressable memories (ACAMs) to approximate an activation function by quantizing outputs of the activation function to a number of bits based on inputs to the activation function from one or more dot product engines. The programming resources find, for multiple of the quantized outputs, corresponding inputs that correspond to the inputs to the activation function that result in respective values in the quantized outputs for respective bits of outputs. For each output bit of the quantized outputs, the programming resources calculate a binary classification problem to find which values of the corresponding inputs result in a specific value in the respective output bit. Furthermore, the programming resources map the binary classification problem to a decision tree implemented in ACAMs by setting programmable resistance values in the one or more ACAMs.

### BACKGROUND

Content addressable memory (CAM) is a type of computing memory used in high-speed searching applications. In CAM, stored data is not searched by its location, but rather by its content. An input value is supplied, and the CAM searches its memory to see if that input value is stored in the memory.

Analog Content Addressable Memory (ACAM) is a type of CAM that can store a range of values in its cell, rather than a single value. This makes ACAM particularly useful for accelerating algorithms with tabular data. The ACAM cell structure can be designed to store ranges with varying levels of precision, enhancing its applicability to real-world machine learning algorithms that often require high precision. ACAMs are powerful, efficient, and fast.

### BRIEF DESCRIPTION OF THE DRAWINGS

Features, aspects, and advantages of the present disclosure will become better understood when the following detailed description is read with reference to the accompanying drawings in which like characters represent like parts throughout the drawings, wherein:

FIG. 1 is a block diagram of a computing system that includes analog content addressable memory (ACAM) to approximate activation functions or attention for a neural network, according to some implementations;

FIG. 2 is a circuit diagram of a non-linear dot product engine (DPE) that includes an analog DPE and an ACAM device, according to some implementations;

FIG. 3 is a block diagram of an ACAM device having an ACAM array with ACAM cells to implement a decision tree, according to some implementations;

FIG. 4 shows an ACAM system that includes an ACAM array and ancillary circuitry used to implement and use the ACAM array, according to some implementations;

FIG. 5 shows a graph of quantization of a sigmoid activation function to be mapped to an ACAM device, according to some implementations;

FIG. 6 is a block diagram of an ACAM system that includes multiple DPEs and ACAM cells connected in parallel, according to some implementations;

FIG. 7 is a flow diagram of an ACAM programming method, according to some implementations;

FIG. 8 is a block diagram of a neural network system that utilizes an ACAM array to approximate softmax as part of an attention computation, according to some other implementations;

FIG. 9 shows a graph of quantization of a logarithmic activation function to be mapped to an ACAM device, according to some implementations;

FIG. 10A shows a decision tree and implementation of a logarithmic activation function in binary code for an ACAM device, according to some implementations;

FIG. 10B shows a decision tree and implementation of a logarithmic activation function in reflective binary code or Gray code for an ACAM device, according to some implementations;

FIG. 11 shows a block diagram of an ACAM system approximating a matrix multiplication (matmul) for an attention mechanism, according to some implementations;

FIG. 12 shows a block diagram of a system that may utilize ACAM approximation for activation function and/or attention computation, according to some implementations; and

FIG. 13 is a block diagram of a computing system that may be used to process a machine learning model, according to some implementations

### DETAILED DESCRIPTION

Crossbar arrays of emerging analog memories, such as memristors, resistive random-access memories (ReRAMs), or phase-change memories (PCMs), organized as dot product engine (DPE), have been widely proposed for accelerating vector-matrix multiplications (VMMs). VMM is one of the main operations in neural network training and inference, such as using decision tree inferencing. However, in modern workloads, activation can account for 50% of the computational time causing the effective improvements through VMM accelerators to be lessened in practice. Machine learning often uses attention mechanisms to determine the relative importance of each component in a sequence by assigning soft weights to components. Furthermore, in modern architectures, attention mechanisms are characterized by data-dependent matrix multiplies, in which matrices are rewritten continuously during inference. However, analog memories also generally suffer from relatively low endurance meaning that rewriting each inference sample may drastically shorten the life of the analog memories. By reducing the number of matrix multiplications, the life of the analog memories may be extended.

Analog content addressable memories (ACAMs) may be used to compute decision tree inferences at least partially in place of costly sequential conditional branching operations. General Compute Elements (GCE) may be used to support arbitrary functions including activation functions. For instance, the GCE may be like those described in U.S. patent application Ser. No. 18/651,218, entitled “Analog Content Addressable Memory for General Computing,” filed on Apr. 30, 2024, which is incorporated by reference in its entirety for all purposes. The GCE, when combined with a dot product engine (DPE), VMM and activations may be computed in the analog domain. The GCE is limited by the precision of the memory technology (e.g., memristors). To compute attention and activations with higher precision (e.g., 4-8 bits) using relatively low precision (e.g., 2 bits) analog memory, inputs are split between multiple low-precision segments dealing with subsets of bits. This split segmentation demands additional circuitry between the DPE and the GCE and the limited precision of the DPE cells causes slices across multiple DPE columns thereby complicating the combination of outputs. Furthermore, compiling arbitrary reduced-precision functions into GCE thresholds may demand listing all possible inputs and outputs resulting in additional overhead.

As discussed herein, a method of computing activation functions may use decision trees to approximate them and directly mapping to ACAMs with minimal peripheral circuit modifications. This direct mapping eliminates the demand for the conversion hardware between the DPE and the ACAM, given the analog output of the DPE can be directly connected to the analog input of the ACAM. The direct mapping may also at least partially eliminate the demand for a new cell (GCE). Furthermore, the direct mapping automates the process for compiling a given function into ACAM thresholds. The resulting combined DPE and ACAM may be referred to as a non-linear DPE (NL-DPE). Furthermore, the NL-DPE may be extended to compute data-dependent matrix multiplies, such as the attention mechanism in transformers, using f=log x as activation functions so that the outputs can be accumulated, with an output equivalent to the matrix multiplies without costly digital multipliers, resulting in increased efficiency and less wear on the analog memories from continuously rewriting matrices.

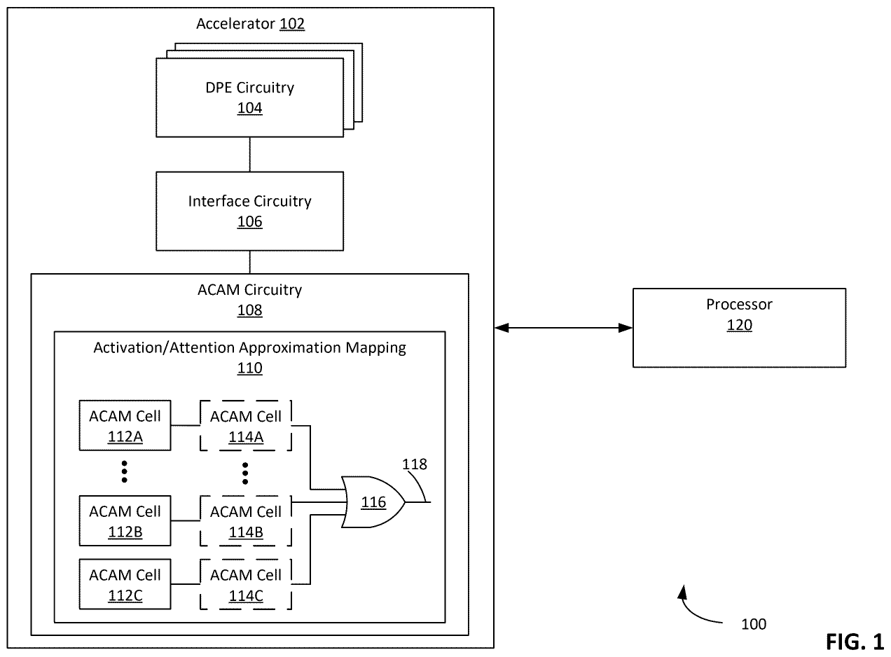

FIG. 1 is a block diagram of a computing system 100, which may be used to implement machine learning and/or other computing functions that may use dot product calculations. The computing system 100 may be implemented in an electronic device that includes an accelerator 102 that includes one or more dot product engine (DPE) circuitries 104. The DPE circuitry 104 performs dot product computations. Dot products are frequently computed in machine learning as dot products are useful for calculating similarity between data vectors, performing weighted sums in neural networks, implementing attention mechanisms, scaling features, performing linear regression, implementing natural language processing, performing convolutional operations, performing dimensionality reduction operations, and/or many other calculations that are useful in machine learning and/or other computing operations.

The DPE circuitry 104 computes a dot product output based on input vectors and/or matrices. The DPE circuitry 104 may be implemented in specialized hardware and/or software on accelerator hardware (e.g., GPU). Regardless, the DPE circuitry 104 is an accelerator that is specialized to perform one of the most common computational actions, matrix multiplication using dot products. A dot product defines how similar input vectors or rows/columns of the matrices are to each other based on the resulting respective output scalar values vectors or vectors. As discussed in more detail below, the DPE circuitry 104 may perform dot product computations in analog or in digital domains.

The DPE circuitry 104 sends, via interface circuitry 106, its outputs (e.g., scalars or vectors) to analog content addressable memory (ACAM) circuitry 108. If the DPE circuitry 104 performs the dot product computation as digital cells, a storage portion of the DPE circuitry 104 (e.g., memristors or resistive RAM (ReRAM)) may be limited by a number of distinguishable conductance levels that can be programmed thereby limiting the number of digital bits stored in the cell (e.g., 2 bits in a cell). The number of bits per cell may be smaller than the number of bits in a weight (e.g., 8 bits) meaning that each cell of the DPE circuitry 104 would perform a slice of the dot product computation. For instance, if the weight is quantized to 8 bits with each cell storing 2 bits, the dot product is computed using 4 DPE cells. The DPE circuitry 104 and/or the interface circuitry 106 may then include combination circuitry to shift the outputs of some of the slices and to combine the slices after shifting.

In other words, regardless of implementation, the interface circuitry 106 may include some circuitry that combines outputs from the DPE circuitry 104 and/or formats data for use in the ACAM circuitry (or ACAM device) 108. For instance, if the DPE circuitry 104 performs computations in digital format, the interface circuitry 106 may include digital-to-analog (DAC) components that format the outputs of the DPE circuitry 104 as analog values that may be used by the ACAM circuitry 108 to generate an output 118.

The ACAM circuitry 108 includes at least one ACAM cell 112 in a first column. Specifically, each ACAM cell 112 has a structure that allows the ACAM circuitry 108 to compute the output of a predetermined function with one or more input variable(s). For instance, the ACAM circuitry 108 may be used to implement activation functions and/or other functions, such as for the attention layer in transformers, approximating activation/functions with decision trees mapped in the ACAM cells 112. The function may be a one-variable function or a multi-variable function. The ACAM circuitry 108 may be able to process the function more efficiently than a general-purpose central processing unit (e.g., the processor 120). Accordingly, the ACAM circuitry 108 may improve the performance of the computing system 100 by improving the way that the computing system 100 is able to approximate activation functions and/or attention mechanisms for machine learning.

In some implementations, the ACAM circuitry 108 may include additional columns of additional ACAM cells 114. Each ACAM cell 112 or 114 receives an input value from the DPE circuitry 104 via the interface circuitry 106. Each ACAM cell 112 or 114 compares the input values as search values to a programmed maximum limit, a minimum limit, or both. The maximum and/or minimum values set a range value output. For ACAM cells that include both the maximum and minimum, the ACAM cells may keep the voltage on a match line at its output high when the input value is between the programmed maximum and minimum values. At least some ACAM cells may define only a maximum or minimum bound meaning that any input values above the minimum or any input values below the maximum are deemed a match. The match lines between ACAM cells may be shared. For instance, a match line from each ACAM cell 112 may be fed into a corresponding ACAM cell 114. For instance, ACAM cells 112A, 112B, and 112C may each respectively share a match line with ACAM cells 114A, 114B, and 114C. These match lines may be chained together so that each check in each ACAM cell in a row forms a logical AND meaning that the output of the rightmost cell indicates that both cells have matched. Likewise, the output from each row may be combined using an OR gate setting an output to a logic high when the input matches the programmed conditions of at least one of the rows of ACAM cells.

As discussed in more detail below, the DPE circuitry 104 and the ACAM circuitry 108 may both work in the analog domain to cause the accelerator 102 to function as a non-linear DPE that performs the dot product computations and activation evaluations more quickly than DPE-based computations that convert between analog and digital domains. Using the capabilities of the ACAM cells 112 and/or 114 to account for error and/or limitations of the precision of the DPE circuitry 108 enables such computations faster and smaller without using additional conversion circuitry (e.g., scale down circuitry) to combine outputs from DPE cells. As such, the programming of the ACAM cells 112 and/or 114 may account for such changes to be performed on the outputs of individual DPE slices (e.g., shifts and/or scale downs) without performing additional conversions between the DPE circuitry 104 and the ACAM circuitry 108.

The processor 120 retrieves executable code from a computer-readable medium and executes the executable code. The executable code may, when executed by the processor 120, cause the processor 120 to implement any functionality described herein. The processor 120 may be a microprocessor, an application-specific integrated circuit, a microcontroller, or the like. The processor 120 may be used to program the minimum and/or maximum values of the ACAM cells 112 and/or 114. Additionally or alternatively, the processor 120 may be used to orchestrate the movement of vectors and/or matrices as inputs to the DPE circuitry 104 for computation and/or receive the results of the DPE circuitry 104 computations and the comparisons in the ACAM circuitry 108 based on the programming of the ACAM cells 112 and 114.

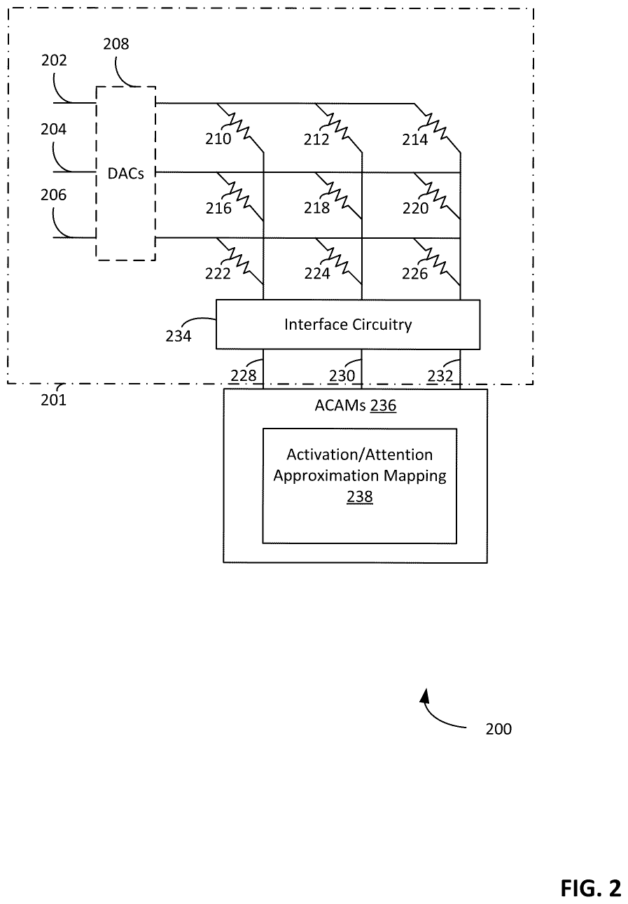

FIG. 2 is a schematic diagram of a non-linear DPE 200 that includes a DPE 201. The DPE 201 may be an example implementation of the DPE circuitry 104. The DPE 201 receives inputs 202, 204, and 206 that correspond to respective components of a vector that may be computed in a dot product operation (e.g., vector-matrix multiplication (VMM)). For instance, the inputs 202, 204, and 206 may be input currents or voltages that correspond to values to be multiplied in the non-linear DPE 200.

The inputs 202, 204, and/or 206 may be received as digital or analog values indicating respective values. In implementations where the inputs are received as digital values, the DPE 201 may include digital-to-analog converters (DACs) 208 to convert the inputs 202, 204, and/or 206 to from digital values to analog values. Additionally or alternatively, the DACs 208 may be conversion circuitry to convert between currents and voltages. For instance, the DACs 208 may convert digital or analog input currents to analog voltages that have different analog levels that each correspond to different values to be computed in the dot product operation.

The DPE 201 includes multiple resistive elements 210, 212, 214, 216, 218, 220, 222, 224, and 226, collectively referred to as resistive elements 210-226. The resistive elements 210-226 store conductance values that correspond to weights to be applied to the inputs. For example, the resistive elements may be memristors or other programmable resistors that store conductance values that correspond to the weights or programmable capacitors that store capacitance values that correspond to the weights. As such, the resistive elements 210-226 may be thought of as the matrix to be applied to the vector formed by the inputs 202, 204, and 206. For example, the input 202 may be multiplied by the conductance values of the resistive elements 210, 212, and 214 as components of respective outputs 228, 230, and 232 by passing the input 202 through the respective resistive elements. Likewise, the input 204 may be multiplied by the conductance values of the resistive elements 216, 218, and 220 as components of the respective outputs 228, 230, and 232 by passing the input 204 through the respective resistive elements. Similarly, the input 206 may be multiplied by the conductance values of the resistive elements 222, 224, and 226 as components of the respective outputs 228, 230, and 232 by passing the input 206 through the respective resistive elements. The outputs of the multiplication of the input 202 by the resistive element 210, the multiplication of the input 204 by the resistive element 216, and the multiplication of the input 206 by the resistive element 222 are added together to form the output 228. Similarly, the outputs of the multiplication of the input 202 by the resistive element 212, the multiplication of the input 204 by the resistive element 218, and the multiplication of the input 206 by the resistive element 224 are added together to form the output 230. Likewise, the outputs of the multiplication of the input 202 by the resistive element 214, the multiplication of the input 204 by the resistive element 220, and the multiplication of the input 206 by the resistive element 226 are added together to form the output 232. Thus, the outputs 228, 230, and 232 have output voltages that are the components of an output vector that is a result of the dot product operations.

In some implementations, the outputs 228, 230, and/or 232 may be consumed as digital values. In such implementations, the outputs 228, 230, and/or 232 are converted from analog signals to digital signals in interface circuitry. The interface circuitry 234 may include analog-to-digital converters (ADCs). Additional or alternative to the analog-to-digital conversions, the interface circuitry may perform other conversions, such as voltages to currents and the like. In other implementations, such as using some implementations of the ACAMs 236, the outputs 228, 230, and the 232 may be output from the respective resistive elements 210-226 as analog values. In such implementations, the interface circuitry 234 may include no ADCs.

In the illustrated embodiment, the non-linear DPE 200 includes ACAMs 236 that consume the outputs 228, 230, and/or 232 in analog formats. The ACAMs 236 may be an example of the ACAM circuitry 108. The ACAMs 236 may implement activation functions and/or other functions typical of the attention mechanism by approximating them with decision trees. As such, the non-linear DPE 200 may have a non-linear response to the inputs and weightings due to the mapping in the ACAMs 236.

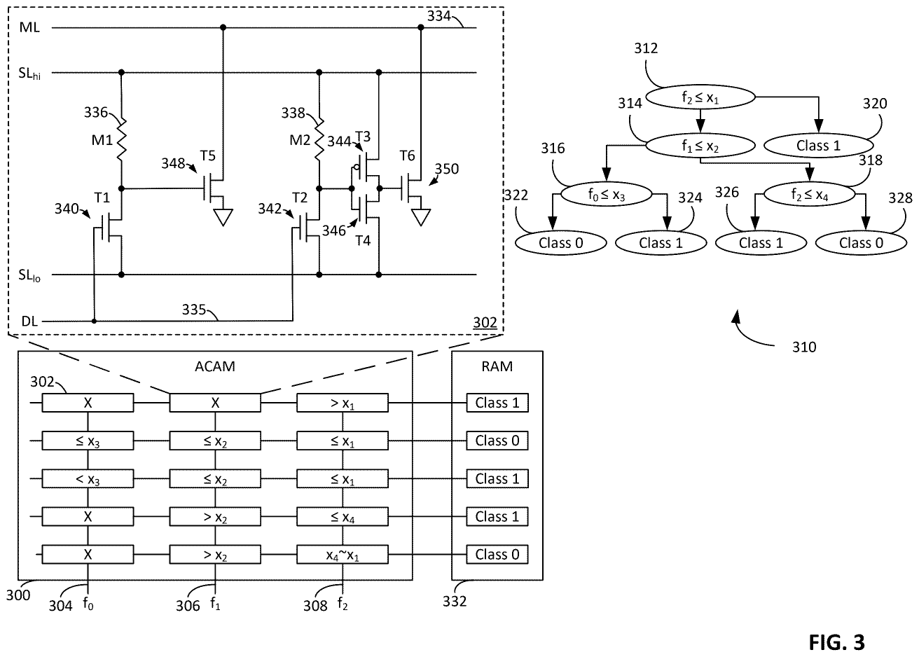

FIG. 3 is a block diagram of an ACAM 300, according to some implementations. For instance, the ACAM 300 may be an example of the ACAM circuitry 108 and/or the ACAMs 236. The ACAM 300 includes an array of ACAM cells 302 as well as multiple peripheral circuits used for programming and operating the array of ACAM cells 302. As subsequently described in greater detail, the ACAM 300 is configured to receive an analog input value corresponding to an input to a predetermined function. The ACAM 300 then outputs a binary code corresponding to an output from the function.

The array of ACAM cells 302 includes multiple ACAM cells that may be arranged in rows and columns. The ACAM cells 302 search multi-level voltages and store analog ranges in their memory. One or more range(s) may be programmed for each ACAM cell 302 of the ACAM array. The ACAM array may be programmed with ranges that are used to compute the output of the predetermined function.

During a search operation, one or more analog input values 304, 306, and/or 308 are input to the ACAM array over data lines DL 335. Using these input values to evaluate information, the ACAM cells 302 may be used to perform compute operations in the analog domain rather than just for storing values. As such, one or more ACAM cells 302 in the ACAM array are arranged in a row of ACAM cells, also referred to as a “ACAM row”. Each ACAM row indicates whether the analog input values are matched by their stored range(s) of each ACAM cell 302 in the ACAM row. Furthermore, each ACAM row may correspond to a path from a root (e.g., top) of a decision tree 310 to a base (e.g., end of path) of the decision tree 310. The stored range(s) encoded in an ACAM cell are compared against a respective analog input value(s). Depending on the implementation of an ACAM cell, a match may occur when an analog input value is inside of the range stored in the ACAM cell 302 or a match may occur when an analog input value is outside of the range stored in the ACAM cell 302. During a write operation, one or more analog input values are communicated to one or more ACAM cells 302 of the ACAM array and stored.

The decision tree 310 is an example of a decision tree that may be implemented using the ACAM 300. However, any other suitable decision trees may be implemented using the ACAM 300. In the illustrated embodiment, the decision tree 310 includes a decision block 312 where the input 308 (e.g., feature 2 (f₂)) is less than or equal to a first value (e.g., 5.95), the path is traversed to the left from the decision block 312, but the decision tree 310 travels right of the decision block 312 if the input 308 is greater than the input 308.

Following the left path from the decision block 312, the decision tree 310 includes a decision block 314 that evaluates whether the input 306 (e.g., feature 1 (f₁)) is less than or equal to a second value (e.g., 1.75). When the input 306 is less than or equal to the second value, the decision tree 310 traverses to the left of the decision block 314, but it traverses to the right of the decision block 314 when the input 306 is greater than the second value.

Following the left path from the decision block 314, the decision tree 310 includes a decision block 316 that evaluates whether the input 304 (e.g., feature 0 (f₀)) is less than or equal to a third value (e.g., 5.35). When the input 304 is less than or equal to the third value, the decision tree 310 traverses to the left of the decision block 316, but it traverses to the right of the decision block 316 when the input 304 is greater than the third value.

Following the right path from the decision block 314, the decision tree 310 includes a decision block 318 that evaluates whether the input 308 is less than or equal to a fourth value (e.g., 2.45). When the input 308 is less than or equal to the fourth value, the decision tree 310 traverses to the left from the decision block 318, but it traverses to the right of the decision block 318 when the input 308 is greater than the fourth value.

Each ACAM row of the ACAM 300 resolves a path of the decision tree from start to finish. For example, the first ACAM row has an ACAM cell 302 that outputs a match to classification block 320 (e.g., class 1) when the input 308 is greater than the first value. In such a situation, it does not matter what the values are for the inputs 304 and 306.

The second ACAM row has ACAM cells that indicate a match to a classification block 322 (e.g., Class 0) when the input 304 is less than or equal to the third value, the input 306 is less than or equal to the second value, and the input 308 is less than or equal to the first value. The third ACAM row has ACAM cells that indicate a match to a classification block 324 (e.g., Class 1) when the input 304 is greater than the third value, the input 306 is less than or equal to the second value, and the input 308 is less than or equal to the first value.

The fourth ACAM row has ACAM cells that indicate a match to a classification block 326 (e.g., Class 1) when the input 306 is greater than the second value and the input 308 is less than or equal to the fourth value. It does not depend on the relationship between the input 304 and the third value. Furthermore, since the fourth value is less than the first value, if the input 308 is less than the fourth value, it is also less than the first value. Accordingly, the fourth ACAM row does not evaluate the relationship between the input 308 and the first value.

The fifth ACAM row has ACAM cells that indicate a match to a classification block 328 (e.g., Class 0) when the input 306 is greater than the second value and the input 308 is between the first value and the fourth value. It does not depend on the relationship between the input 304 and the third value. Furthermore, since a single ACAM cell 302 may store a range from a maximum value and a minimum value, a single ACAM cell 302 may be used to evaluate whether the input 308 is between the first value and the fourth value.

The output of each ACAM row may be a digital signal indicating match or no match. Other storage (e.g., RAM) 332 may be used to store what each match signal indicates. For instance, a first part of the storage 332 may indicate that a match in the first, third, or fourth ACAM rows indicates Class 1 while a match in the second or fifth ACAM rows indicates Class 0. The number of match groupings and/or classification groups may vary based on implementation and respective decision trees 310.

FIG. 3 also shows a circuit diagram for an ACAM cell 302 of the ACAM 300, according to some implementations. An ACAM cell 302 is connected to the match line ML 334, a data line DL 335, a high source line SLₕᵢ, a low source line SLₗₒ, and a reference node (or ground). The ACAM cells 302 in an ACAM row share a ML 334. The ACAM cells 302 are ACAM cells that store a single range that may be used to test whether an analog input value is inside of the stored range. As used herein, a range refers to a range of voltages that is stored in an ACAM cell 302, where the range of voltages is defined by an upper bound and a lower bound.

Each ACAM cell 302 is shown as an example having a six-transistor-two-memristor (6T2M) circuit implementation. Specifically, an ACAM cell 302 includes two memristors: a first memristor M1 336 and a second memristor M2 338. The ACAM cell 302 includes six transistors: transistor T1 340, transistor T2 342, transistor T3 344, transistor T4 346, transistor T5 348, and transistor T6 350. In the illustrated example, the transistors T1-T6 can be implemented as metal-oxide semiconductor field-effect transistors (MOSFETs), or the like.

A memristor is a non-volatile electronic memory device, whose resistance can be programmed. Thus, analog values can be stored in (or encoded on) the ACAM cell 302 by programming the conductances of the M1 336 and M2 338. The range stored in an ACAM cell 302 is defined by an upper bound (encoded by a conductance of the M1 336) and a lower bound (encoded by a conductance of the M2 338). The conductance of a memristor may be programmed by imposing a voltage (corresponding to the desired conductance) across the memristor.

In this implementation, an ACAM cell 302 stores a bound of a range by encoding the bound in the M1 336 and the M2 338. The ACAM cell 302 includes the M1, the T1 340 as a control transistor, the T5 348 as a pull-down transistor in a first part of the ACAM cell 302. The M1 is connected in series with the T1 in what can be considered as a first memristor-transistor pair M1/T1. The output of the memristor-transistor pair M1/T1 is connected to the gate of the T5 348.

The ACAM cell 302 also includes the M2 338, the T2 342 as a control transistor, the T6 350 as a pull-down transistor, and the T3 344 and the T4 346 connected as an inverter. The M2 338 is connected in series with the T2 342 in what can be considered as a memristor-transistor pair M2/T2. The output of the memristor-transistor pair M2/T2 is inverted by the T3 344 and the T4 346 as an inverter. The output of the inverter is connected to the gate of the T6 350.

The pull-down transistors, T5 348 and T6 350, are connected in series between the ML 334 and a reference node (e.g., ground). Thus, the ML 334 may be pulled to ground if the T5 348 and/or the T6 350 are turned on by the M1/T1 or the M2/T2.

During a write operation, programming voltages are applied to the M1 336 and the M2 338 to program the range for the ACAM cell 302. This is done by applying a voltage to the high source line SLₕᵢ, to increase the conductance of the M1 336 and/or the M2 338 or applying a voltage to the low source line SLₗₒ, to decrease the conductance of the M1 336 and/or M2 338. A voltage may also be applied to the DL 335 during the write operation.

During a search operation, an analog voltage (e.g., one of the inputs 304, 306, or 308) is applied to the DL 335 to provide the analog input value for comparison (in the analog domain) with the range stored in the ACAM cell 302. The DL 335 is electrically connected to the gate of the T1 340 and to the gate of the T2 342. Therefore, the ACAM cell 302 receives the analog input value via the DL 335. In operation, the ACAM cell 302 matches when the analog input value is outside of the stored range, defined via the conductances of the M1 336 and the M2 338.

Whether a match is found between the analog input value (received via the DL 335) and the range stored in the M1 336 and the M2 338 is indicated over the ML 334. The ML 334 is pre-charged to a voltage Vₘₗ before a search operation begins. As the search operation is performed, the ML 334 remains high (e.g., remains at the voltage Vₘₗ) to indicate a match if the analog input value applied to the ACAM cell 302 via the DL 335 is matched by the stored range. Alternatively, if the analog input value applied to the ACAM cell 302 via the DL 335 is not matched by the stored range that is encoded in the M1 336 and M2 338, the ML 334 transitions low to indicate a mismatch by discharge through the T5 348 or the T6 350. Since all ACAM cells 302 in an ACAM row share an ML 334, the ML 334 remains high only if all of the ACAM cells 302 in an ACAM row have conditions that are matched by respective inputs and programmed values stored in the respective memristors of each ACAM cell 302.

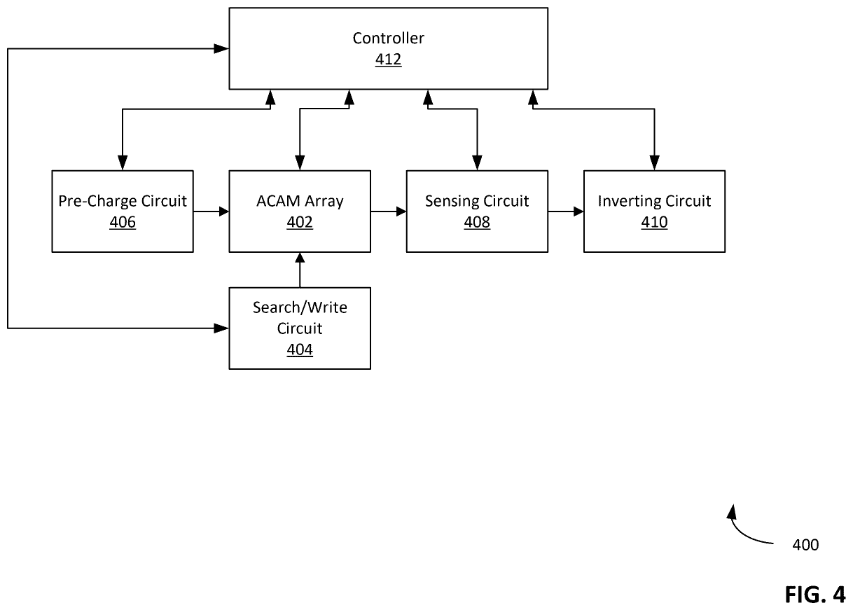

FIG. 4 is a block diagram of an ACAM system 400 that includes an ACAM array 402 of multiple ACAM cells, such as the ACAM cells 302. The ACAM system 400 also includes a search/write circuit 404. The search/write circuit 404 performs a search operation or a write operation for the ACAM array 402. The search/write circuit 404 may include a digital-to-analog converter (DAC), drivers, and the like. The DAC is used to apply write voltages to ACAM cells of the ACAM array 402 during a write operation, and to apply search voltages to ACAM cells of the ACAM array 402 during a search operation. As previously discussed, the search/write operations may involve setting appropriate analog voltage levels to represent desired analog input values. For example, the DAC may apply write voltages to program the stored range(s) for ACAM cells of the ACAM array 402 or may apply search voltages to test whether the search voltages are matched by the range(s) programmed in ACAM cells of the ACAM array 402. Specifically, the search/write circuit 404 may apply voltages to data lines (e.g., DL 335) of the ACAM array 402 via appropriate drivers.

In implementations where the search/write circuit 404 receives an input (e.g., inputs 304, 306, or 306) as digital input value, the search/write circuit 404 may convert the digital input value to an analog input value and provide the analog input value to the ACAM array 402. In some implementations, the search/write circuit 404 may receive an analog input value and provide the analog input value to the ACAM array 402 without conversion into the analog domain.

The ACAM system 400 may also include a pre-charge circuit 406. The pre-charge circuit 406 pre-charges a match line for one or more ACAM cells of the ACAM array 402 to a voltage Vₘₗ before a search operation begins. As previously discussed, during a search operation, the match line of the ACAM cells remains high to indicate a match if the analog input values applied to the ACAM cells are matched by the range(s) stored in the ACAM cells of the ACAM row. Alternatively, in some implementations, the match line transitions low as a current in the match line discharges through pull-down transistors of an ACAM cell to indicate a mismatch if the analog input values applied to the ACAM cells are not matched by the range(s) stored in the ACAM cells.

The ACAM system 400 may also include a sensing circuit 408. The sensing circuit 408 senses the outputs of the ACAM cells of the ACAM array 402. The sensing circuit 408 may include a sense amplifier for each ACAM row. The match line of each ACAM row is connected to a respective sense amplifier. A sense amplifier may be used during a search operation to detect if a match line of an ACAM row is high (indicating a match with one or more analog input values) or low (indicating a mismatch with the analog input values) and/or for decoding in a storage element (e.g., storage 332).

The ACAM system 400 may also include an inverting circuit 410. The inverting circuit 410 is connected to the sensing circuit 408. This connection allows the inverting circuit 410 to receive the detected outputs from the sensing circuit 408. The inverting circuit 410 may include an inverter for each sense amplifier. The sense amplifier of each ACAM row may be connected to an inverter. As previously alluded to, each match line of the ACAM array 402 is either high (indicating a match with analog input values) or low (indicating a mismatch with analog input values), and the state of each match line is determined by the sensing circuit 408. The inverting circuit 410 is used to invert the logical states of the match lines (determined by the sensing circuit 408). Thus, if a match line is high (indicating a match) the inverting circuit 410 may flip that state to low. Similarly, if a match line is low (indicating a mismatch) the inverting circuit 410 may flip that state to high.

The ACAM system 400 may also include a controller 412 for controlling the components of the ACAM system 400. The controller 412 may be part of the ACAM device (e.g., ACAM device 108) and/or may be outside of the ACAM device, such as a host processor for a host system. The controller 412 may control the inverting circuit 410, the sensing circuit 408, the pre-charge circuit 406, and the search/write circuit 404. The controller 412 may include a digital control circuit such as a microcontroller, an application-specific integrated circuit, or the like. The digital control circuit provides control signals and/or data to the sensing circuit 408 and the search/write circuit 404. For example, the digital control circuit may be used to drive the DAC of the search/write circuit 404 as well as control and coordinate the operation of the DAC. The controller may include other components, such a clock circuit for temporalizing operations in the ACAM array 402.

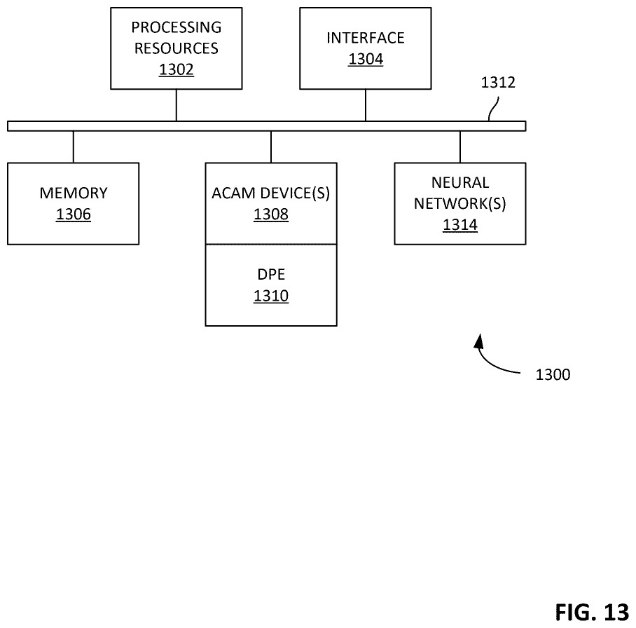

The ACAM system 400 may be implemented as an integrated circuit (IC) on a semiconductor substrate using suitable microfabrication techniques. Such an IC would integrate the ACAM array 402, the search/write circuit 404, the pre-charge circuit 406, the sensing circuit 408, the inverting circuit 410, and/or any other components (e.g., the controller 412) onto a single chip or multiple chiplets. The resulting IC package may be integrated into larger systems, such as the computing system of FIG. 13.

Since ACAMs can be used to compute whether analog inputs are within certain ranges, ACAMs as part of a non-linear DPE can be used to approximate an activation function or other functions typical of the attention mechanism for neural networks. For instance, a DPE (e.g., DPE 201) may compute a dot product on an input to the DPE (e.g., x) to generate a dot product (e.g., xW) that is input to an ACAM (e.g., ACAMs 236 or 300). The activation function may be mapped in the ACAM. For instance, an activation function of the neural network may be a particular function (e.g., sigmoid) of the output (e.g. xW).

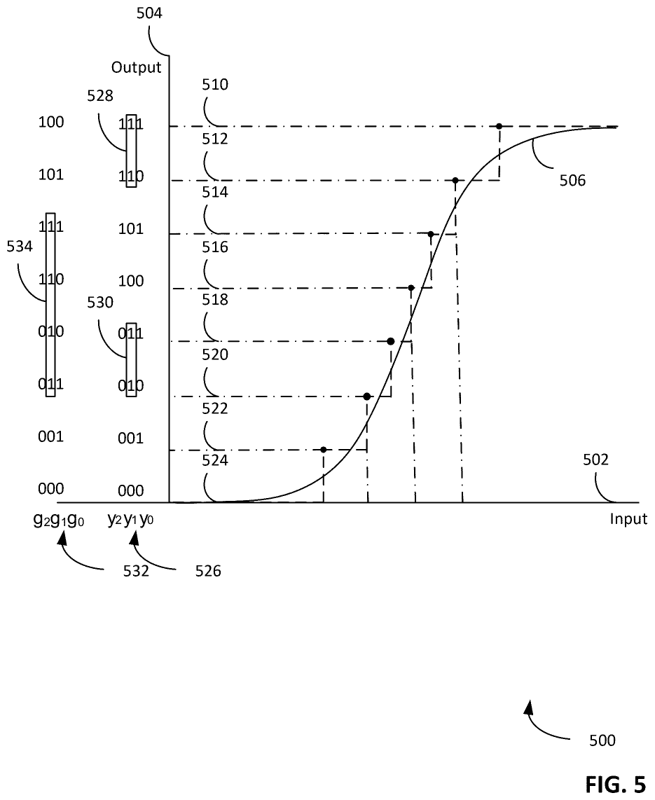

FIG. 5 shows a graph 500 of a sigmoid activation function. The graph 500 includes an input 502 located along a horizontal axis. The input 502 is an input to an ACAM, such as the ACAMs 236 or 300. The input 502 may be input to the ACAM as an output from a DPE, such as the DPE 201. The graph 500 also shows an output 504 located along a vertical axis. The output 504 may be the output from the ACAM based on a sigmoid activation function 506 where output=sigmoid (input). Although a sigmoid shape is shown as the sigmoid activation function 506, any other activation function may be used, such as rectified linear units (ReLUs), hyperbolic tangent (tanh), softmax, and/or the like.

The graph 500 is quantized into a fixed-bit width. For instance, the illustrated output 504 is mapped to three bits (maximum of 8 quantized outputs), but it may be mapped into any suitable number of bits (e.g., 1, 2, 3, 4, 5, 6, 7, 8, or more bits). In the illustrated graph 500, the output 504 is divided into quantized outputs 510, 512, 514, 516, 518, 520, 522, and 524. Each quantized output may be assigned output y bits 526 (e.g., y₀, y₁, y₂). The output y bits are traditional binary numbers from 0 (e.g., 000 in 3-bit binary) to 7 (e.g., 111 in 3-bit binary). By examining the individual y bits, each y bit may be mapped to particular ranges as a binary classification problem. For example, in regions 528 and 530, y₁ is 1. Otherwise, y₁ is 0. Using the sigmoid activation function 506, y₁ is 1 when the input 502 is between −0.91 and 0.28 and when the input 502 is above 1.79. These values may then be mapped to a decision tree implemented an ACAM as discussed above to quickly compute an output value during operation of the neural network. Similarly, each bit of the output 504 may be likewise mapped and computed during operation of the neural network. By using ACAM-based computes, the neural network may determine an activation quickly without additional conversion between the DPEs and ACAMs. Furthermore, the ACAM mapping can be performed without complex digital multiplications and/or tying up other processing resources, such as microprocessors, CPUs, GPUs, neural networks, and/or the like.

In some implementations, the quantized output may be grouped into Gray code (or reflected binary code) bits, such as output g bits 532. The output g bits 532 (e.g., g₀, g₁, g₂) are in a binary numeral system where successive values differ by only one bit that may enhance the grouping by reducing the number of ranges to be implemented in the ACAMs. For instance, instead of regions 528 and 530 of the output y bits 526 being mapped to a decision tree, a single region 534 of the output g bits 532 may be mapped to a decision tree. Specifically, g₁ is 1 when the input 502 is between −0.91 and 1.79 and is 0 for any other values of the input 502.

Although FIG. 5 depicts a mapping of a single input to a single output, some implementations may have an output that is based on multiple inputs. For instance, the dot product operation may be split between multiple DPEs using weight slicing (e.g., analog slicing or digital slicing) where a first slice of the weight is stored in a first DPE and a second slice of the weight is stored in a second DPE. The outputs from the different DPEs may be sent to different ACAM cells.

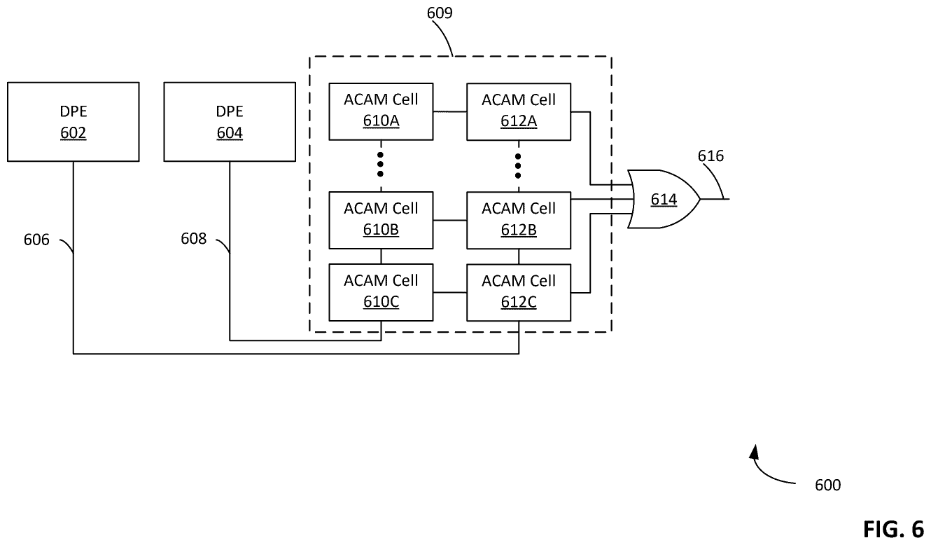

FIG. 6 is a block diagram of a non-linear DPE system 600 that includes multiple DPEs 602 and 604. The DPEs 602 and 604 may be examples of the DPEs 201. The DPE 602 may store a first slice of weights and implement a first part of the dot product using the first slice of weights. The DPE 602 may store a second slice of weights and implement a second part of the dot product using the second slice of weights. The first and second parts of dot products may be combined using DPE circuitry in non-ACAM implementations depending on whether the weight slicing is analog or digital slicing. In digital slicing, the first or second parts are shifted before adding the parts together. In analog slicing, the second part may be scaled before adding the parts together. However, such processes may be omitted in non-linear DPEs by using ACAMs to map activation functions with adding and such shifts and/or scaling built into the mapping.

The non-linear DPE system 600 includes an ACAM 609 that receives a first input 606 carrying the first part of the dot product and a second input 608 carrying the second part of the dot product. The ACAM 609 may be an example of the ACAMs 236 or 300. The ACAM 609 includes ACAM cells 610A, 610B, 610C, 612A, 612B, and 612C that may be examples of the ACAM cells 302. The ACAM cells 610A, 610B, and 610C (collectively referred to as ACAM cells 610) are used to perform decision tree mapping to approximate a first part of an activation function and/or other functions such as the one typical of attention mechanism, based on the first input 606 from the DPE 602. Likewise, the ACAM cells 612A, 612B, and 612C (collectively referred to as ACAM cells 612) are used to perform decision tree mapping to approximate a second part of the activation function and/or other functions such as the one typical of the attention mechanism based on the second input 608 from the DPE 604. ACAM rows of ACAM cells may be mapped to decision trees without shifting the first input 606 or the second input 608 by incorporating such changes in the mapping. As discussed below, this mapping may be made by determining each possible quantized input to each possible quantized output, by using sample distributions, by randomly or periodically sampling historical data, mapping transfer functions using digital computations of inputs to outputs, mapping transfer functions using lookup tables, and/or other suitable mechanisms for tracking output results based on respective input values.

Although three ACAM cells 610 and three ACAM cells 612 are shown, any number of ACAM cells 610 and/or 612 may be implemented to map a respective decision tree based on the first input 606 and the second input 608. Furthermore, the number of ACAM cells may differ between the first input 606 and the second input 608. Additionally or alternatively, the first input 606 and/or the second input 608 may use a single column of ACAM cells as shown or may use multiple columns of ACAM cells. Regardless of implementation, the outputs of each ACAM row (e.g., match line ML 334) may be combined via an OR gate 614 to generate an output 616. The output 616 may correspond to a single bit of an output (e.g., y₁) using the techniques discussed above. Additional bits may be computed using similar ACAM cells to map additional bits of an output. Each of the outputs 616 may be appended together sequentially to form a multi-bit output (e.g., 3-bit output, 8-bit output, or any other suitable number of bits).

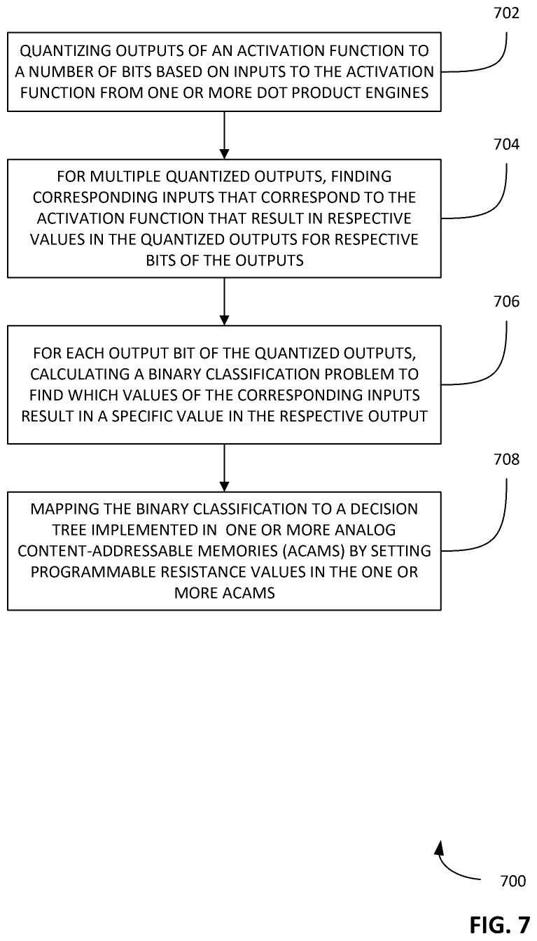

FIG. 7 is a process 700 that may be used to program an ACAM (e.g., ACAM 236, 300, or 609) as an accelerator for an activation function for a neural network. The process 700 may be implemented using one or more processing resources, such as a microprocessor, a central processing unit (CPU), a graphics processing unit (GPU), and/or any other suitable processor.

The one or more processing resources quantize outputs of an activation function to a number of bits based on inputs to the activation function from one or more dot product engines (block 702). For instance, outputs of a continuous activation function may be divided into a finite number of quantized sets. An example of the continuation activation function may include a sigmoid function, a logarithmic function, any other suitable function, and/or a combination of multiple functions. The number of quantized output groups may be a number representable by the number of bits. For instance, using x bits (e.g., 3 bits), the number of quantized output groups may be 2^{x} (e.g., 8). The one or more processing resources may subdivide the range of outputs for the activation function into the number of quantized bits by dividing the output range into equal parts.

For multiple quantized outputs, the one or more processing resources find corresponding inputs that correspond to the activation function that result in respective values in the quantized outputs for respective bits of the outputs (block 704). For instance, the one or more processing resources may sample inputs to the activation function and determine the corresponding outputs. The sampling may include randomly sampling actual inputs as they arrive during a running process and/or may include sampling a normal distribution. Additionally or alternatively, the one or more processing resources may compute boundaries between subsets of the quantized outputs using mathematical modeling. Regardless of implementation, the one or more processing resources track analog input values to each bit of the quantized outputs.

Using the tracked relationship between the analog input values to bits of the quantized outputs, the one or more processing resources calculate a binary classification problem to find which values of the corresponding inputs result in a specific value (e.g., “1”) in a respective bit (e.g., y₁) of a respective quantized output (e.g., y consisting of y₀, y₁, and y₃). For instance, for each respective bit, the one or more processing resources may determine which quantized output groups correspond to the specific value and which respective analog input values correspond to those groups. For instance, as shown in FIG. 5, the region 530 includes quantized output groups “010” and “011” that the second bit corresponds to “1” and the analog inputs fall between −0.91 and 0.28 in binary code. Similarly, the region 534 includes quantized output groups “011,” “010,” “110,” and “111” that the second bit corresponds to “1” and the analog inputs fall between −0.91 and 1.79 in Gray code (reflected binary code). In other words, the output bits may be binary coded or reflected binary coded.

In other words, the one or more processing resources may determine where a bit of the quantized output groups transitions to the specific value from another value (e.g., “0”) at a first corresponding analog input value and set the first corresponding analog input value as a lower bound for a range of a decision tree. Likewise, the one or more processing resources may determine where a bit of the quantized output groups transitions from the specific value to the other value at a second corresponding analog input value and set the second corresponding analog input value as an upper bound for the range of a decision tree. The one or more processing resources may do this for each transition to and/or from the specific value for each bit in an index of the quantized output groups. These output mappings may be determined by training a neural network using the input and output values implemented by the one or more processing resources. Additionally or alternatively, these output mappings may be manually calculated using the one or more processing resources by inspecting input and output data. At least some ranges may be one-sided with only an upper bound or a lower bound as part of the binary classification problem.

Once the one or more processing resources have determined the bounds for each region, the one or more processing resources may map the binary classification to a decision tree implemented in one or more analog content-addressable memories (ACAMs) by setting programmable resistance values in the one or more ACAMs (block 708). For instance, one or more processing resources may program each range found in the binary classification in a respective ACAM cell (e.g., ACAM cell 302) by programming the upper bound in a first memristor (e.g., M1 336) and a lower bound in a second memristor (e.g., M2 338). Each range for a respective bit may be combined using combination logic (e.g., OR gate 614). Each respective bit may be concatenated together to form a multi-bit output that indicates how the analog input value has been transformed by the ACAM acting as a transformer for a neural network. During operation of the neural network, the ACAM may receive input analog values and output the multi-bit output based on the programmed mapping. Since the ACAMs can receive analog inputs from DPEs, the programmed ACAM acts as an accelerator without converting between digital and analog domains. Furthermore, the ACAMs may be used to implement non-linear DPEs without shifting/scaling and adding weight slices enabling the use of low-precision weights and further improving operation of computing system that utilizes the ACAM accelerator to compute activation functions.

As previously noted, the activation function may be a sigmoid function, a logarithmic function, another suitable function type, or a compound function formed of multiple functions. In some situations using programmed ACAMs, an activation function may be used to compute or approximate attention by using f=log x as an activation function so that after the linear layer and activations, the outputs may be accumulated without costly matrix multiplications thereby increasing efficiency of the attention mechanism using the programmed ACAMs.

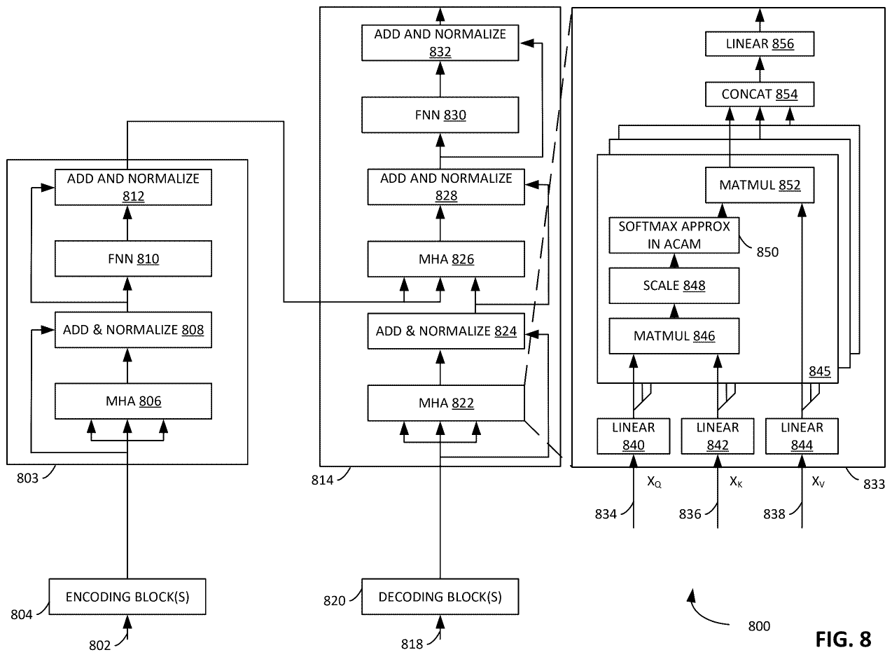

FIG. 8 is a block diagram of a transformer 800 of a neural network that implements one or more attention mechanisms. The transformer 800 may be implemented using one or more processing resources, including hardware and/or software. The transformer 800 receives inputs 802 at one or more encoding block(s) 804. The encoding block(s) 804 may embed the inputs as vectors and/or add positional encoding to indicate the absolute and/or relative position of encoded tokens in an input sequence.

After positional encoding, the encoded tokens are transmitted to an encoder 803. The encoder 803 includes a multi-head attention block (MHA) 806. MHAs will be discussed in more detail below in relation to MHA 833. The MHA 806 may be a self-attention block that compares tokens within the input sequence to each other to compute attention weights. A high value in the attention weight between a pair of tokens indicates that they are syntactically or semantically related. Thus, high attention weights indicate important tokens that the model should “attend” to. For example, verbs and modifying adverbs may be closely related like nouns and modifying adjectives while unrelated parts of speech may have low attention weights.

The output of the MHA 806 is added to their original input tokens and normalized in an add and normalize block 808. The normalization may use residual connections that backpropagate gradient updates that may otherwise become lost due to gradient descent. In other words, the backpropagation to estimate gradients using the residual connections may iteratively adjust weights and biases to minimize the cost function through gradient descent.

The normalized output of the add and normalized block 808 is then fed into a feed-forward neural network (FNN) 810 where information flows in one direction from input to output without loops or cycles using layers of interconnected neurons. However, the encoder 803 may include repeats of the attention (e.g., MHA 806) and FNN 810. After each FNN 810, the outputs of the respective FNN 810 are added to their original input tokens and normalized in an add and normalize block 812. Like the add and normalize block 808, the add and normalize block 812 may use residual connections that backpropagate gradient updates that may otherwise become lost due to gradient descent. After normalization, the encoded input tokens are output from the encoder 803 to a decoder 814.

In addition to the encoded tokens from the encoder 803, the decoder 814 receives an output sequence 818 that has been processed so far in the neural network transformer 800. The output sequence 818 is also encoded into vectors and/or added with positional encoding in decoding block(s) 820. The output sequence 818, like the input sequence, are processed in an MHA 822 for self-attention to compare tokens of the output sequence with each other.

The outputs of the MHA 822 are added to their original output tokens and normalized in an add and normalize block 824. Like the add and normalize blocks 808 and 812, the add and normalize block 824 may use residual connections that backpropagate gradient updates that may otherwise become lost due to gradient descent.

After normalization, the encoded output tokens are sent to a cross-attention block (MHA 826). The MHA 826 also receives the encoded input tokens from the encoder 803. The MHA 826, unlike the MHA 806 and the MHA 822, compares the encoded tokens of the input sequence to tokens of the output sequence. The cross-attention MHA 826 and the self-attention MHAs 806 and 822 function the same except that one input of the MHA 826 differs from its other inputs (e.g., output sequence versus input sequence) unlike the homogenous inputs of the MHAs 806 and 822.

The outputs of the MHA 826 are added to their original output tokens and normalized in an add and normalize block 828. Like the add and normalize blocks 808 812, and 824, the add and normalize block 828 may use residual connections that backpropagate gradient updates that may otherwise become lost due to gradient descent.

The normalized output of the add and normalized block 828 is then fed into a feed-forward neural network (FNN) 830 where information flows in one direction from input to output without loops or cycles using layers of interconnected neurons. However, the decoder 814 may include repeats of the attention (e.g., MHA 822 and/or MHA 826) and FNN 830. After each FNN 830, the outputs of the respective FNN 830 are added to their original tokens and normalized in an add and normalize block 832. Like the add and normalize blocks 808 812, 824, and 828, the add and normalize block 832 may use residual connections that backpropagate gradient updates that may otherwise become lost due to gradient descent. The output of the add and normalize block 832 may be a processed output sequence (e.g., output sequence 818) of the transformer 800 that is fed back into the decoder 814.

FIG. 8 also shows an MHA 833 that may be an example of the MHAs 806, 822, and/or 826. As previously noted, the MHAs 806, 822, and/or 826 may function the same except that the inputs of the MHA 826 are heterogenous while the inputs of the MHAs 806 and 822 are homogenous. In other words, inputs 834, 836, and 838 of the MHAs 806 and 822 may be the same. For instance, the MHA 806 may receive three copies of input sequence tokens while the MHA 822 receives three copies of output sequence tokens and the MHA 826 receives encoded input tokens from the encoder 803 along with outputs sequence tokens. Generally, the input 834 may correspond to a query X_{Q} input, the input 836 may correspond to a key X_{K}input, and the input 838 may correspond to a value X_{V} input. Each token in a sequence is a separate input for X_{Q}, X_{K}, and X_{V}.

The MHA 833 includes linear neural networks 840, 842, and 844 to divide the respective inputs 834, 836, and 838 by projecting the inputs tokens into smaller embeddings before sending them to multiple heads 845. In some implementations, each head may include different linear networks with different attention weights for different heads 845. Although three heads are shown, any number of heads 845 may be included in an MHA, such as 2, 3, 4, or more heads.

Each head 845 includes a matrix multiplication block (matmul) 846 that multiplies matrices/vectors of inputs 834 and 836 using a dot product. For instance, such dot product operations may be implemented in the DPE 201. The more similar the inputs, the larger the resulting dot product. In some implementations, the result of multiplication may be scaled down (e.g., multiply by the square root of the dimensions of the vectors/matrices) in scale block 848. Scaling helps reduce the magnitude and ensures that its outputs that are to be input a softmax function are suitable.

In some implementations, the output of the scale block 848 may be transmitted to a softmax function. The softmax function outputs the attention weights for the respective head 845. The results from the softmax function are between 0 and 1 where the sum of all paired tokens sum to 1. In some implementations, the output of the scale block 848 may be masked to ignore certain positions by setting them equal to a specific value where softmax of the specific value (e.g., −∞) is 0.

However, the formula for a softmax includes multiple matrix multiplications that are continuously rewritten during an inference. As previously noted, analog memories have relatively low endurance where rewriting the values for each inference sample may not be feasible. One mechanism for avoiding such issues may be to approximate attention in ACAMs without explicitly performing a softmax operation (block 850). For instance, as described in more detail below a logarithmic function, additions, and exponentiation function implemented at least partially using ACAMs as discussed above may be used to approximate an attention mechanism without the explicit computation of a softmax function or the data dependent matrix multiplies.

Regardless of how the attention weights are determined (e.g., using softmax or ACAM approximation), the attention weights are then multiplied by the input 838 (block 852). The larger the attention weight, the more the model attends to those values while the smaller attention weights are attended to less heavily by the model.

The outputs from each head 845 are concatenated together in a contact block 854 that is then passed through another linear neural network 856. As each head can learn to focus on different aspects, the outputs of the heads 845 may have different weights and different projections.

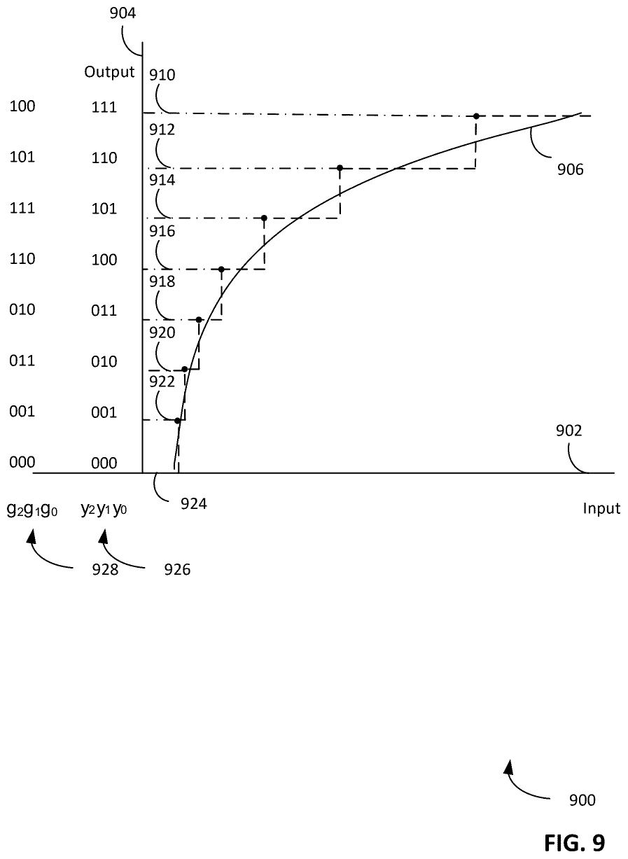

FIG. 9 shows a graph 900 of a logarithmic activation function. The graph 900 includes an input 902 located along a horizontal axis. The input 902 is an input to an ACAM, such as the ACAMs 236 or 300. The input 902 may be input to the ACAM as an output from a DPE, such as the DPE 201. The graph 900 also shows an output 904 located along a vertical axis. The output 904 may be the output from the ACAM based on a logarithmic activation function 906 where output=log (input).

The graph 900 is quantized into a fixed-bit width. For instance, the illustrated output 904 is mapped to three bits (maximum of 8 quantized outputs), but it may be mapped into any suitable number of bits (e.g., 1, 2, 3, 4, 5, 6, 7, 8, or more bits). In the illustrated graph 900, the output 904 is divided into quantized outputs 910, 912, 914, 916, 918, 920, 922, and 924. Each quantized output may be assigned output y bits 926 (e.g., y₀, y₁, y₂). The output y bits are traditional binary numbers from 0 (e.g., 000 in 3-bit binary) to 7 (e.g., 111 in 3-bit binary). By examining the individual y bits, each y bit may be mapped to particular ranges as a binary classification problem like discussed above in relation to the graph 500 of FIG. 5. These values may then be mapped to a decision tree implemented an ACAM as discussed above to quickly compute an output value during operation of the neural network. Similarly, each bit of the output 904 may be likewise mapped and computed during operation of the neural network. By using ACAM-based compute for logarithm computation, the accelerator may approximate a multiplication by first converting analog inputs x in digital log(x) and then accumulating them, given a summation in the log domain is equivalent to a multiplication outside the log domain. The log-multiplication can be then converted back with an exponential function, which can similarly be mapped to the ACAM. The multiplication may represent the attention scores of the attention mechanism in transformers. Logarithm and exponential functions can be then used to compute the attention scores.

In some implementations, the quantized output may be grouped into Gray code (or reflected binary code) bits, such as output g bits 928. The output g bits 928 (e.g., g₀, g₁, g₂) are in a binary numeral system where successive values differ by only one bit that may enhance the grouping by reducing the number of ranges to be implemented in the ACAMs.

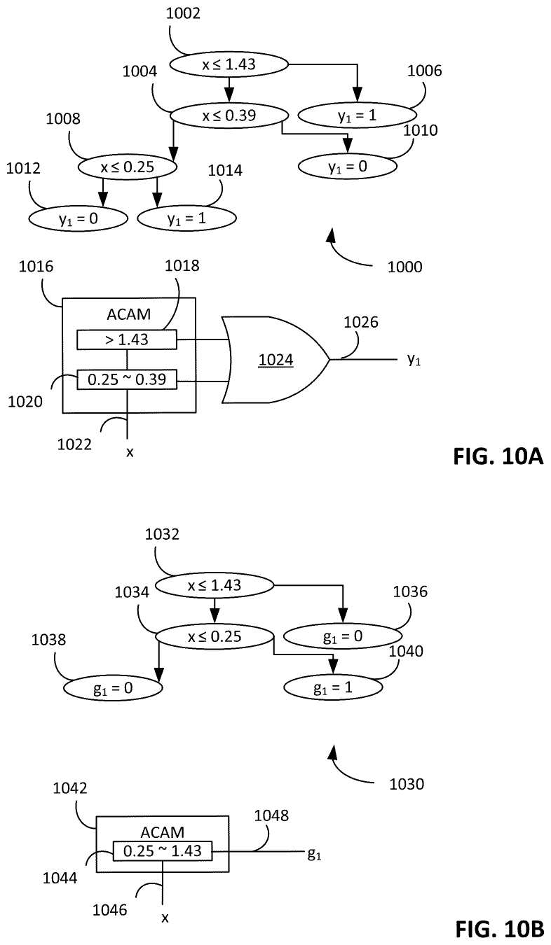

FIG. 10A is a sample decision tree 1000 that may be mapped to by a bit (e.g., y₁) in an ACAM using quantization of a logarithmic activation function (e.g., logarithmic activation function 906). The decision tree 1000 includes a decision block 1002 that determines whether an input value x to an ACAM 1016 is less than or equal to 1.43. If x is less than or equal to 1.43, the decision tree 1000 uses a decision block 1004 in the ACAM 1016 to determine whether x is less than or equal to 0.39. If x is greater than 1.43, the decision tree 1000 indicates that y₁ equals 1 (block 1006).

If x is less than or equal to 0.39, the decision tree 1000 uses a decision block 1008 in the ACAM 1016 to determine whether x is less than or equal to 0.25. If x is greater than 0.39 (but less than or equal to 1.43), the decision tree 1000 indicates that y₁ equals 0 (block 1010). If x is less than or equal to 0.25, the decision tree 1000 indicates that y₁ is 0 (block 1012). However, if x is greater than 0.25 (but less than or equal to 0.39), the decision tree indicates that y₁ is 1 (block 1014).

The decision tree 1000 is mapped to the ACAM 1016. The ACAM 1016 may be an example of the ACAM 300. The decision tree 1000 may be mapped to the ACAM 1016 in ACAM cells 1018 and 1020. The ACAM cells 1018 and 1020 may be examples of the ACAM cell 302. The ACAM cell 1018 is mapped to a range of input x 1022 greater than 1.43 while the ACAM cell 1020 is mapped to a range of input x 1022 between 0.25 and 0.39. Thus, if the input x 1022 is an analog value greater than 1.43 or between 0.25 and 0.39, an input to an OR gate 1024 is 1 resulting in an output bit y₁ 1026 to be equal to 1. If the input x 1022 is an analog value outside of these ranges, the output bit y₁ 1026 is 0.

FIG. 10B is a sample decision tree 1030 that may be mapped to a bit (e.g., g₁) in an ACAM using quantization of a logarithmic activation function (e.g., logarithmic activation function 906) using Gray codes. The decision tree 1030 includes a decision block 1032 that determines whether an input value x to an ACAM 1042 is less than or equal to 1.43. If x is less than or equal to 1.43, the decision tree 1030 uses a decision block 1034 in the ACAM 1016 to determine whether x is less than or equal to 0.25. If x is greater than 1.43, the decision tree 1030 indicates that g₁ equals 0 (block 1036). If x is less than or equal to 0.25, the decision tree 1030 indicates that y₁ is 0 (block 1038). However, if x is greater than 0.25 (but less than or equal to 1.43), the decision tree indicates that g₁ is 1 (block 1040).

The decision tree 1030 is mapped to the ACAM 1042. The ACAM 1042 may be an example of the ACAM 300. The decision tree 1030 may be mapped to the ACAM 1042 in a single ACAM cell 1044. The ACAM cell 1044 may be an example of the ACAM cell 302. The ACAM cell 1044 is mapped to a range of input x 1046 between 0.25 and 1.43. Thus, if the input x 1046 is an analog value between 0.25 and 1.43, an output bit g₁ 1048 is equal to 1. Otherwise, g₁ is equal to 0.

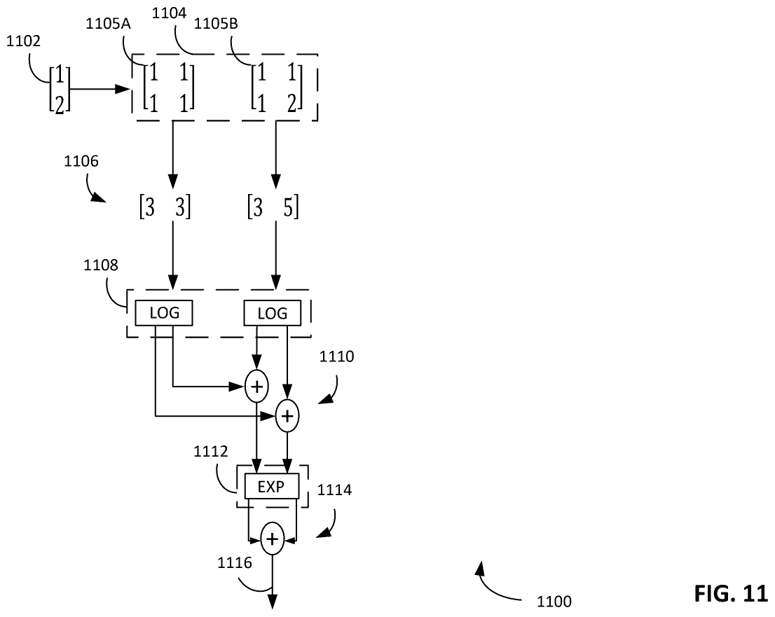

FIG. 11 is a block diagram of a process for using a quantized logarithmic and exponential function mapped to an ACAM to approximate the multiplication of data dependant matrix multiplies in a neural network, such the product of keys and queries matrixes in the attention mechanism of a Transfomer model. The linear layers (e.g. 840, 842) followed by a MATMULT (846) may be implemented by a non-linear DPE 1100, such as the non-linear DPE 200 that includes a DPE (e.g., DPE 201) and ACAMs (e.g., ACAMs 236 or 300). An input 1102 is received at the non-linear DPE 1100. For instance, the input 1102 may be an input 834 (X_{Q}) that is the same as input 836 (X_{K}). The input 1102 is input to the DPE 1104 as analog or digital values. When received as a digital value, the DPE 1104 may convert the digital value to an analog value using a digital-to-analog converter.

A DPE 1104 stores weights 1105A and 1105B. The weights 1105A may correspond to the query weights (W^{Q}) to be applied to the X_{Q} input while the weights 1105B may correspond to the key weights (W^{K}) to be applied to the XK input. Although the X_{Q} and X_{K} inputs may be the same, namely X=X_{Q}=X_{K}, the query weights and the key weights are different. The DPE 1104 computes the dot product in the analog domain to generate an analog dot product 1106 that includes XW^{Q} and XW^{K}.

The analog dot product 1106 is transmitted, in the analog domain, to an ACAM 1108. The ACAM 1108 maps logarithmic activation functions as previously discussed in relation to FIGS. 9, 10A, or 10B. The ACAM 1108 outputs a log (XW^{Q}) and log (XW^{K}) that are added in adders 1110. These added logs are then transmitted to another ACAM 1112 that maps an exponentiation function to generate attention scores.

The attention scores are then added together in an adder 1114. As discussed below, a logarithm may be computed for this sum of exponentiation functions to determine log_{softmax} (Sᵢ), where Sᵢ is a specific attention score with an index i using the following equation:

log_{softmax}(Sᵢ)=Sᵢ−log Σexp(Sᵢ) (Equation 1).

Using Equation 1, a computing device may compute attention by computing log(A), where A is attention using the following equation:

log(A)=log_{softmax}(S)+log(XW^{V}) (Equation 2),

where X is an input to the MHA (e.g., input 838). Also, log(XW^{V}) can be computed using a NL-DPE as previously discussed for log(XW^{K}) and log(XW^{Q}). Using equation 2, A may be computed using the following equation:

A=exp(log(A)) (Equation 3).

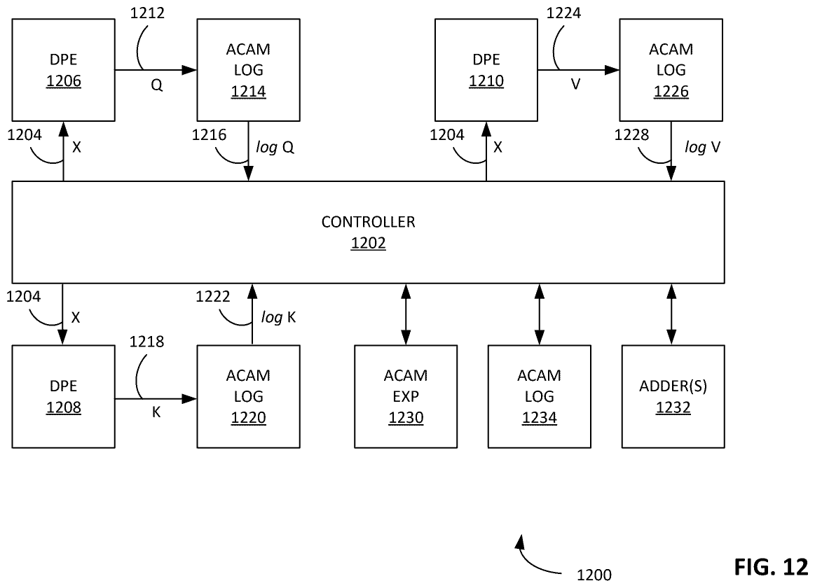

FIG. 12 is a block diagram of an NL-DPE system 1200 that may use DPE and ACAM acceleration to approximate attention based at least in part on logarithmic and exponential activation function-based ACAM acceleration. The NL-DPE system 1200 includes a controller. The controller may be any processing resource, such as a processor including a microprocessor, central processor, graphics processor, programmable logic device, an application-specific integrated circuit, and the like to control a data flow in the attention approximation.

The controller 1202 may compute linear layers for multiple vectors of a neural network using non-linear DPEs. For instance, the controller 1202 may send an input 1204 (e.g., input sequence or output sequence) to DPEs 1206, 1208, and 1210 when the self-attention is to be computed. However, if implementing cross-continuation in a particular head (e.g., head 845), a different input may be sent to the DPE 1210. The DPEs 1206, 1208, and 1210 may be examples of the DPE 201.

In a first non-linear DPE including the DPE 1206, the DPE 1206 outputs Q 1212 that is a dot product (XW^{Q}) of the input 1204 (X) and query weights (W^{Q}). An ACAM 1214 maps a logarithmic activation function to generate log Q 1216 that is returned to the controller 1202. The ACAM 1214 may map the logarithmic activation function similar to the techniques discussed in relation to FIGS. 9, 10A, and 10B.

In a second non-linear DPE including the DPE 1208, the DPE 1208 outputs K 1218 that is a dot product (XW^{K}) of the input 1204 (X) and key weights (W^{K}). An ACAM 1220 maps a logarithmic activation function to generate log K 1222 that is returned to the controller 1202. The ACAM 1220 may map the logarithmic activation function similar to the techniques discussed in relation to FIGS. 9, 10A, and 10B.

In a third non-linear DPE including the DPE 1210, the DPE 1210 outputs V 1224 that is a dot product (XW^{V}) of the input 1204 (X) and value weights (W^{V}). An ACAM 1226 maps a logarithmic activation function to generate log V 1228 that is returned to the controller 1202. The ACAM 1226 may map the logarithmic activation function similar to the techniques discussed in relation to FIGS. 9, 10A, and 10B.

The computations of log Q 1216, log K 1222, and log V 1228 may be computed in parallel as linear layers. Log Q 1216 and log K 1222 may be transmitted from the controller 1202 to an adder circuit 1232 and then to an ACAM 1230 that maps an exponentiation function to compute attention scores as previously discussed. The log K 1222 may be transposed before transmittal to the ACAM 1230.

The exponentiation function output of the summation of the log Q 1216 and the log K 1222 is then transmitted back to the controller 1202. The exponentiation may be calculated for Sᵢ where i is the index. Each indexed Sᵢ may be added in the adder(s) 1232. This sum may be transmitted back to the controller 1202 to then be transmitted to an ACAM 1234 to compute a logarithm of the sum. The controller 1202 or another processing resource may then approximate the log of the score function for a specific Si by subtracting the logarithm of the sum from the Sᵢ. The controller 1202 or another processing resource may then compute attention from the approximation by adding log V 1228 to the approximated softmax of the score function and passing the new sum through an exponentiation function (e.g., via the ACAM 1230).

Although the illustrated implementation of the ACAM system 1200 includes three non-linear DPEs, a separate ACAM for exponentiation, and a separate ACAM for logarithmic functions outside of the non-linear DPEs, at least some ACAMs may be shared between computations or additional ACAMs may be included to reduce reuse of an ACAM through the computation of attention.

FIG. 13 is a block diagram of a computing system 1300, which may be used to process a machine learning model, according to some implementations. The computing system 1300 may be implemented in an electronic device. Examples of electronic devices include host devices (e.g., servers, personal computers, mobile devices, etc.), network devices (e.g., routers, switches, access points, etc.), and the like.

The computing system 1300 may be utilized in any data processing scenario, including stand-alone hardware, mobile applications, or combinations thereof. Further, the computing system 1300 may be used in a computing network, such as a public cloud network, a private cloud network, a hybrid cloud network, other forms of networks, or combinations thereof. In one example, the methods provided by the computing system 1300 are provided as a service over a network by, for example, a third party. The computing system 1300 may be implemented on one or more hardware platforms, in which the modules in the system may be executed on one or more platforms. Such modules may run on various forms of cloud technologies and hybrid cloud technologies or be offered as a Software-as-a-Service that may be implemented on or off a cloud network.

To achieve its desired functionality, the computing system 1300 includes various hardware components. These hardware components may include a processing resources 1302, an interface 1304, a memory 1306, ACAM device(s) 1308, and dot product engine circuitries (DPE) 1310. The hardware components may be interconnected through a number of buses 1312 and/or network connections. In one example, the processing resources 1302, the interface 1304, the memory 1306, and a non-linear DPE including the ACAM device(s) 1308 and the DPE 1310 may be communicatively coupled via the buses 1312, such as a PCI-Express bus.

The processing resources 1302 retrieve executable code from the memory 1306 and executes the executable code. The executable code may, when executed by the processing resources 1302, cause the processing resources 1302 to implement any functionality described herein. The processing resources 1302 may be a microprocessor (e.g., a CPU or a GPU), an application-specific integrated circuit, a programmable logic device (e.g., an FPGA), a microcontroller, or the like.

The interface 1304 enables the processing resources 1302 to interact with various other hardware components, external and internal to the computing system 1300. For example, the interface 1304 may include interface(s) to input/output devices, such as, for example, a display device, a mouse, a keyboard, etc. Additionally or alternatively, the interface 1304 may include interface(s) to storage devices, network devices, host devices, or the like.

The memory 1306 may include various types of memory, including volatile and nonvolatile memory. For example, the memory 1306 may include Random-Access Memory (RAM), Read-Only Memory (ROM), a Hard Disk Drive (HDD), and/or the like. Different types of memory may be used for different data storage needs. For example, the processing resources 1302 may boot from ROM, maintain nonvolatile storage in an HDD, execute program code stored in RAM, and store data under processing in RAM. The memory 1306 may include a non-transitory computer readable medium that stores instructions for execution by the processing resources 1302. One or more modules within the computing system 1300 may be partially or wholly embodied as software and/or hardware for performing any functionality described herein.

The ACAM device(s) 1308 is an accelerator. For example, as discussed above, the ACAM device 1308 may be an example of the ACAM 300 and may be used by the processing resources 1302 to accelerate processing of a machine learning model using a neural network 1314 (that may be implemented separately or using the one or more processing resources). The ACAM device(s) 1308 is different than the processing resources 1302. The ACAM device(s) 1308 includes ACAM cells (e.g., ACAM cells 302), which are used for computing instead of data storage for the processing resources 1302. Specifically, each ACAM cell has a structure that allows the ACAM device(s) 1308 to compute the output a predetermined function (e.g., attention or activation function) with one or more input variable(s). The function may be a one-variable function or a multi-variable function. The ACAM device(s) 1308 may be able to process the function more efficiently than a general-purpose central processing unit (e.g., the processing resources 1302). Accordingly, the ACAM device(s) 1308 may improve the performance of the computing system 1300 itself for attention computation and/or approximating activation functions during an inference.

Although this disclosure describes or illustrates particular operations as occurring in a particular order, this disclosure contemplates the operations occurring in any suitable order. Moreover, this disclosure contemplates any suitable operations being repeated one or more times in any suitable order. Although this disclosure describes or illustrates particular operations as occurring in sequence, this disclosure contemplates any suitable operations occurring at substantially the same time where appropriate.

One or more specific aspects of the present disclosure are described above. In an effort to provide a concise description of these aspects, all features of an actual implementation may not be described in the specification. It should be appreciated that in the development of any such actual implementation, as in any engineering or design project, numerous implementation-specific decisions are made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various aspects of the present disclosure, the articles “a,” “an,” “the,” and “said” are intended to mean that there are one or more of the elements. The terms “comprising,” “including,” and “having” are intended to be inclusive and mean that there may be additional elements other than the listed elements.

While certain features of the present disclosure have been illustrated and described herein, many modifications and changes will occur to those skilled in the art. It is, therefore, to be understood that the appended claims are intended to cover all such modifications and changes as fall within the true spirit of the present disclosure.

What is claimed is:

1. A method, comprising:
quantizing, by one or more processing resources, outputs of an activation function to a number of bits based on inputs to the activation function from one or more dot product engines;
for a plurality of the quantized outputs, finding, by the one or more processing resources, corresponding inputs that correspond to the inputs to the activation function that result in respective values in the quantized outputs for respective bits of outputs;
for each output bit of the quantized outputs, calculating, by the one or more processing resources, a binary classification problem to find which values of the corresponding inputs result in a specific value in the respective output bit; and
mapping, by the one or more processing resources, the binary classification problem to a decision tree implemented in one or more analog content-addressable memories (ACAMs) by setting programmable resistance values in the one or more ACAMs.

2. The method of claim 1, comprising slicing a weight between at least two dot product engines of the one or more dot product engines, wherein mapping the result of the decision tree comprises:
mapping a first output of a first dot product engine of the one or more dot product engines to a first column of ACAM cells of the one or more ACAMs; and
mapping a second output of a second dot product engine of the one or more dot product engines to a second column of ACAM cells of the one or more ACAMs.

3. The method of claim 2, wherein slicing the weight comprises:
sending first bits of the weight in a first digital slice to the first dot product engine; and
sending second bits of the weight in a second digital slice to the second dot product engine.

4. The method of claim 2, wherein slicing the weight comprises:
sending a first value of the weight in a first analog slice to the first dot product engine; and
sending a second value of the weight in a second analog slice to the second dot product engine, wherein the second value is based at least in part on a deviance between the weight and the first value.

5. The method of claim 1, comprising implementing inferencing using the mapped one or more ACAMs by receiving inputs at the one or more ACAMs from the one or more dot product engines.

6. The method of claim 5, wherein implementing inferencing comprises receiving the inputs as outputs from the one or more dot product engines without conversion by conversion circuitry between the one or more dot product engines and the one or more ACAMs.

7. The method of claim 1, comprising:
computing, by the one or more dot product engines, linear layers of the activation function; and
computing, by the one or more processing resources, attention scores based at least in part on the computed linear layers and the one or more ACAMs.

8. The method of claim 7, comprising:
approximating, by the one or more ACAMs, a normalized exponential function based at least in part on the attention scores; and
computing attention based at least in part on the approximated normalized exponential function.

9. The method of claim 8, wherein the normalized exponential function comprises a softmax function, and approximating the softmax function comprises quantizing a logarithmic function as the activation function.

10. A non-transitory, computer-readable medium, comprising computer-readable instructions that, when executed by one or more processing resources, cause the one or more processing resources to:
quantize outputs of an activation function to a number of bits based on inputs to the activation function from one or more dot product engines;
for a plurality of the quantized outputs, find corresponding inputs that correspond to the inputs to the activation function that result in respective values in the quantized outputs for respective bits of outputs;
for each output bit of the quantized outputs, calculate a binary classification problem to find which values of the corresponding inputs result in a specific value in the respective output bit; and
map the binary classification problem to a decision tree implemented in one or more analog content-addressable memories (ACAMs) by setting programmable resistance values in the one or more ACAMs.

11. The non-transitory, computer-readable medium of claim 10, wherein the computer-readable instructions, when executed by the one or more processing resources, are configured to cause the one or more processing resources to slice a weight between at least two dot product engines of the one or more dot product engines, wherein mapping the result of the decision tree comprises:
mapping a first output of a first dot product engine of the one or more dot product engines to a first ACAM cell of the one or more ACAMs; and
mapping a second output of a second dot product engine of the one or more dot product engines to a second ACAM cell of the one or more ACAMs.

12. The non-transitory, computer-readable medium of claim 11, wherein slicing the weight comprises:
sending first bits of the weight in a first digital slice to the first dot product engine; and
sending second bits of the weight in a second digital slice to the second dot product engine.

13. The non-transitory, computer-readable medium of claim 11, wherein slicing the weight comprises:
sending a first value of the weight in a first analog slice to the first dot product engine; and
sending a second value of the weight in a second analog slice to the second dot product engine, wherein the second value is based at least in part on a deviance between the weight and the first value.

14. The non-transitory, computer-readable medium of claim 10, wherein the computer-readable instructions, when executed by the one or more processing resources, are configured to cause the one or more processing resources to manage inferencing using the mapped one or more ACAMs by causing transmission of inputs at the one or more ACAMs from the one or more dot product engines.

15. The non-transitory, computer-readable medium of claim 14, wherein implementing inferencing comprises causing the one or more ACAMS to receive the inputs as outputs from the one or more dot product engines without conversion by conversion circuitry between the one or more dot product engines and the one or more ACAMs.

16. The non-transitory, computer-readable medium of claim 10, wherein the computer-readable instructions, when executed by the one or more processing resources, are configured to cause the one or more processing resources to:
cause the one or more dot product engines to compute linear layers of the activation function; and
manage computation of attention scores based at least in part on the computed linear layers using the one or more ACAMs.

17. The non-transitory, computer-readable medium of claim 16, wherein the computer-readable instructions, when executed by the one or more processing resources, are configured to cause the one or more processing resources to:
approximate a normalized exponential function via the one or more ACAMs based at least in part on the attention scores; and
manage computation of attention based at least in part on the approximated normalized exponential function.

18. The non-transitory, computer-readable medium of claim 17, wherein the normalized exponential function comprises a softmax function, and approximating the softmax function comprises quantizing a logarithmic function as the activation function.

19. A system, comprising:
one or more dot product circuitries configured to compute, in the analog domain, dot products on input values and stored weights;
one or more analog content addressable memories (ACAMs) configured to receive the dot products from the one or more dot product circuitries in the analog domain;
one or more processing resources configured to:
quantize outputs of an activation function to a number of bits based on inputs to the activation function from the one or more dot product circuitries to the one or more ACAMs;
for a plurality of the quantized outputs, find corresponding inputs that correspond to the inputs to the activation function that result in respective values in the quantized outputs for respective bits of outputs;
for each output bit of the quantized outputs, calculate a binary classification problem to find which values of the corresponding inputs result in a specific value in the respective output bit; and
map the binary classification problem to a decision tree implemented in the one or more ACAMs by setting programmable resistance values in the one or more ACAMs.

20. The system of claim 19, wherein the one or more processing resources are configured to approximate a softmax function via the one or more ACAMs, and the activation function comprises a logarithmic activation function and an exponentiation activation function as part of an approximation for a softmax function of an attention computation.
